(19) United States
(12) Patent Application Publication
(10) Pub. No.: US 2026/0148371 A1
(43) Pub. Date: May 28, 2026

(54) ETCHING ENDPOINT DETERMINATION METHOD

(71) Applicant: CHIPBOND TECHNOLOGY CORPORATION, Hsinchu City (TW)

(72) Inventors: Yu-Lun Hsiao, Taoyuan City (TW); Jun-Wei Huang, Taoyuan City (TW)

(21) Appl. No.: 19/382,467

(22) Filed: Nov. 7, 2025

(30) Foreign Application Priority Data
Nov. 22, 2024 (TW) 113145213

(51) Int. Cl. G06T 7/00; G06T 5/40; G06T 5/73; G06T 7/10; H01L 21/66

(52) U.S. Cl. CPC G06T 7/001; G06T 5/40; G06T 5/73; G06T 7/10; H10P 74/238; G06T 2207/10024; G06T 2207/20021; G06T 2207/20132; G06T 2207/30148; G06T 2207/30168

(57) ABSTRACT

In an etching endpoint determination method, a semiconductor device is etched by an etching system, a semiconductor image is captured by an optical system and sent to a computing device which includes a HV determination module, a AI determination module and a determination module, the HV determination module extracts HV channel data, determines whether reaching the etching endpoint according to the HV channel data and output a HV channel etching endpoint determination signal, the AI determination module processes the semiconductor image to get a feature-enhanced image, determines whether reaching the etching endpoint according to the feature-enhanced image and output an AI etching endpoint determination signal, the determination module receives the HV channel etching endpoint determination signal and the AI etching endpoint determination signal, determines whether reaching the etching endpoint according to the two signals.

### CROSS-REFERENCE TO RELATED APPLICATIONS

This application claims priority to R.O.C Patent Application No. 113145213 filed Nov. 22, 2024, the disclosure of which is hereby incorporated by reference in its entirety.

### FIELD OF THE INVENTION

This invention relates to an etching endpoint determination method, and more particularly to an etching endpoint determination method through image recognition.

### BACKGROUND OF THE INVENTION

Etching is a material removal process and is widely used in semiconductor manufacture for fine patterning thin films on wafers. Conventional semiconductor etching process involves photoresist coating, photolithography, thin-film etching and photoresist stripping. In thin-film etching, a thin film visible from a photoresist patterned by photolithography is removed to obtain a patterned thin film. Dry etching is a removal process using plasma ions to react with or bombard thin films, but drying etching apparatuses are complex with higher cost. Wet etching is a process to remove thin films not covered by patterned photoresist using etching solution, apparatuses for wet etching are lower in cost than that for dry etching so wet etching is used widely than dry etching. There are many factors affecting rate of the reaction between etching solution and thin films such as flow, temperature, stress and vacuum, thus, it is not easy to determine wet etching endpoint. In addition, too long etching time may lead lateral over-etching of thin film owing to wet etching is isotropic, and too short etching time may remain residues of thin films. Precision and accuracy determination of etching endpoint is a critical technology for etching process.

### SUMMARY OF THE INVENTION

One object of the present invention is to provide an etching endpoint determination method. Etching endpoint of an etching process can be determined by dual modes, HV determination module and AI determination module, to improve efficiency and yield of the etching process.

An etching endpoint determination method of the present invention includes the steps as follow. A semiconductor device is etched by an etching system. A semiconductor image of the etched semiconductor device is captured by an optical system. A computing device receives the semiconductor image from the optical system, a HV determination module of the computing device extracts HV channel data of the semiconductor image, determines whether the semiconductor device reach the etching endpoint using the HV channel data and output a HV channel etching endpoint determination signal, an AI determination module of the computing device processes the semiconductor image to a feature-enhanced image, determines whether the semiconductor device reach the etching endpoint using the feature-enhanced image and output an AI etching endpoint determination signal. A determination module of the computing device receives the HV channel etching endpoint determination signal and the AI etching endpoint determination signal, determines whether the semiconductor device reach the etching endpoint according to the HV channel etching endpoint determination signal and the AI etching endpoint determination signal.

The HV determination module and the AI determination module in the computing device are provided to process the semiconductor image and determine whether the semiconductor device reach the etching endpoint. The present invention can avoid wrong determination of the etching endpoint due to one way determination and improve etching efficiency and manufacture yield.

### BRIEF DESCRIPTION OF DRAWINGS

FIG. 1 is a flow chat illustrating an etching endpoint determination method in accordance with one embodiment of the present invention.

FIG. 2 is a block diagram illustrating an etching system, an optical system and a computing device in accordance with one embodiment of the present invention.

FIG. 3 is a flow chat illustrating extraction of HV channel data of a semiconductor image performed by a HV determination module in accordance with one embodiment of the present invention.

FIG. 4 is a flow chat illustrating image feature enhancement performed by an AI determination module in accordance with one embodiment of the present invention.

### DETAILED DESCRIPTION OF THE INVENTION

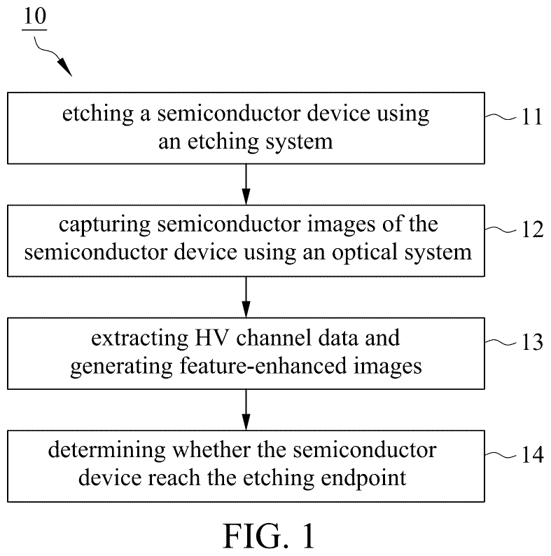

FIG. 1 is a flow chat provided to illustrate an etching endpoint determination method 10 in according one embodiment of the present invention. The etching endpoint determination method 10 includes a step 11 of etching a semiconductor device using an etching system, a step 12 of capturing semiconductor images of the semiconductor device using an optical system, a step 13 of extracting HV channel data and generating feature-enhanced images and a step 14 of determining whether the semiconductor device reach the etching endpoint.

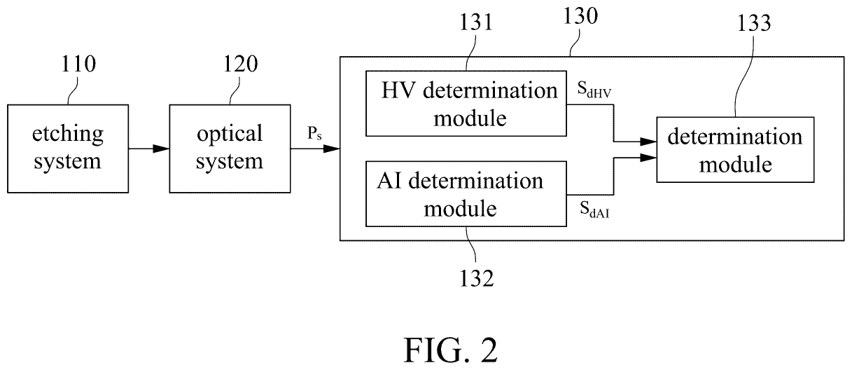

FIG. 2 is a block diagram of a system architecture used to implement the etching endpoint determination method 10. The system architecture includes an etching system 110, an optical system 120 and a computing device 130, and in this embodiment, the etching system 110 is a wet etching apparatus, the optical system 120 is a camera, and the computing device 130 is a computer. A semiconductor device is etched by the etching system 110 in the step 11, and preferably, the semiconductor device is a wafer.

With reference to FIGS. 1 and 2, in the step 12, the optical system 120 captures a semiconductor image Pₛ of the semiconductor device during etching. After the equipment automation program (EAP) in the etching system 110 issues commands to etch the semiconductor device, the etching system 110 needs to operate a certain period and then inject etching solution into a chamber for etching the semiconductor device. In this embodiment, the optical system 120 will begin to capture the semiconductor image Pₛ of the semiconductor device after the etching system 110 operates over a period of booting time. Accordingly, the optical system 120 will not capture images of the semiconductor device not be etched yet to affect etching endpoint determination. Owing to different etching systems need different booting time, the period of booting time will be set after testing.

With reference to FIGS. 1 and 2, in the step 13, the computing device 130 receives the semiconductor image Pₛ from the optical system 120. A HV determination module 131 in the computing device 130 extracts HV channel data of the semiconductor image Pₛ, determines whether the semiconductor device reach the etching endpoint according to the HV channel data and outputs a HV channel etching endpoint determination signal S_{dHV}. The semiconductor image Pₛ is processed by an AI determination module 132 of the computing device 130 to become a feature-enhanced image. The AI determination module 132 determinates whether the semiconductor device reach the etching endpoint based on the feature-enhanced image and outputs an AI etching endpoint determination signal S_{dAI}.

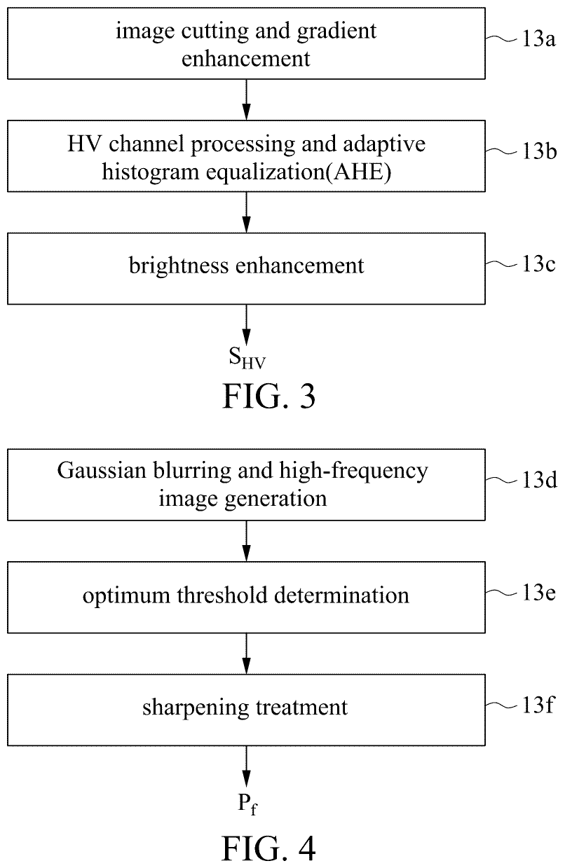

With reference to FIGS. 2 and 3, in this embodiment, extraction of the HV channel data S_{HV} in the semiconductor image Pₛ by the HV determination module 131 includes a sub-step 13a of image cutting and gradient enhancement, a sub-step 13b of HV channel processing and adaptive histogram equalization, and a sub-step 13c of brightness enhancement.

In the sub-step 13a of image cutting and gradient enhancement, the HV determination module 131 cut the semiconductor image Pₛ to get a semiconductor image cut including only the semiconductor device in order to narrow down determination range of the image. The HV determination module 131 calculates a horizontal gradient and a vertical gradient of the semiconductor image cut, the horizontal gradient is the pixel intensity change across the horizontal dimension of the semiconductor image cut, and the vertical gradient is the pixel intensity change across the vertical dimension of the semiconductor image cut. In this embodiment, the horizontal and vertical gradients of the semiconductor image cut are obtained through simple interpolation method, and they can highlight feature contours. The HV determination module 131 uses the horizontal and vertical gradients to calculate a gradient magnitude, and in this embodiment, the HV determination module 131 uses the Euclidean distance between the horizontal and vertical gradients as the gradient magnitude. In final, the HV determination module 131 adds the gradient magnitude to pixels of the semiconductor image cut to enhance pixel gradient of the semiconductor image cut thereby reducing noises in the semiconductor image cut and enhancing feature contours of the semiconductor image cut.

In the sub-step 13b of HV channel processing and adaptive histogram equalization, the HV determination module 131 converts RGB pixels of the semiconductor image cut into HSV pixels, divides the semiconductor image cut with HSV pixels into multiple grids without overlapping and computes a gray level histogram of each of the grids. The HV determination module 131 uses a predetermined contrast ratio threshold to limit the contrast ratio of the gray level histogram of each of the grids to get a limited gray level histogram of each of the grids. The HV determination module 131 computes a cumulative distribution function of the limited gray level histogram of each of the grids, uses the cumulative distribution function to equalize the pixels of the grids for local contrast enhancement, and performs interpolation of the pixels located at the grid edge to get an equalized semiconductor image for smoothing pixel transition.

The sub-step 13b of HV channel processing and adaptive histogram equalization can enhance uniformity of local contrast to highlight details, and the gray level histogram processing after dividing the semiconductor image cut into the grids without overlapping can equalize brightness and contrast ratio of different regions on the semiconductor image cut to keep the details of different regions and improve accuracy of etching endpoint determination. The whole wafer surface is etched by the etching solution during etching process and the semiconductor image cut is more detailed, thus the semiconductor image cut is suitable for adaptive histogram equalization.

In the sub-step 13c of brightness enhancement, the HV determination module 131 calculates a quotient of V components of the pixels in the equalized semiconductor image to V components of the HSV pixels in the semiconductor image cut, and compensates H component of each of the pixels in the semiconductor image cut to become a compensated H component value using the quotient. In other words, H component of each of the pixels in the semiconductor image cut is compensated to the compensated H component value by multiplying the H component with the quotient. The compensated H component value of each of the pixels in the semiconductor image cut and the V component of the equalized semiconductor image are the HV channel data, and in this embodiment, the HV channel data are the sum of the compensated H component value of each of the pixels in the semiconductor image cut and the V component of the equalized semiconductor image.

The images captured by the optical system 120 are coherent images so the HV channel data obtained from the HV determination module 131 are multiple data collected during a continuous period. In this embodiment, the HV determination module 131 performs the addition of the multiple HV channel data and determines whether the semiconductor device reach the etching endpoint according to the sum. If the sum of the multiple HV channel data is greater than a HV channel threshold, the HV channel etching endpoint signal S_{dHV} outputting from the HV determination module 131 represents that the semiconductor device reaches the etching endpoint. Oppositely, if the sum of the multiple HV channel data is less than the HV channel threshold, the HV channel etching endpoint signal S_{dHV} represents that the semiconductor device has yet to reach the etching endpoint. In another embodiment, the HV determination module 131 performs a moving average treatment on the HV channel data before etching endpoint determination, and the HV determination module 131 determines whether the semiconductor device reach the etching endpoint according to the average of the HV channel etching endpoint signals S_{dHV} collected during a period of time.

With reference to FIGS. 2 and 4, in this embodiment, generation of the feature-enhanced images includes a sub-step 13d of Gaussian blur and high-frequency image generation, a sub-step 13e of optimum threshold determination and a sub-step 13f of sharpening treatment.

In the sub-step 13d of Gaussian blur and high-frequency image generation, the AI determination module 132 applies binarization to the semiconductor image to generate a binarized semiconductor image and cut the binarized semiconductor image to get a binarized semiconductor image cut including only the semiconductor device to reduce image processing data volume. Next, the AI determination module 132 blur the binarized semiconductor image cut using Gaussian blur to get a blurred image, extracts high-frequency components in the blurred image, and adds the high-frequency components to the blurred image to get a sharp semiconductor image cut. The edge contrast of the sharp semiconductor image cut is enhanced so the features of the sharp semiconductor image cut are clearer than that of the semiconductor image.

In the sub-step 13e of optimum threshold determination, the AI determination module 132 gets an initial threshold by calculating an average of gray values of all pixels in the sharp semiconductor image cut, and the AI determination module 132 classifies the pixels with a gray value higher than the initial threshold to a high gray value group and classifies the pixels with a gray value lower than the initial threshold to a low gray value group. The average of the gray values of the pixels in the high gray value group calculated by the AI determination module 132 is viewed as a high threshold, the average of the gray values of the pixels in the low gray value group calculated by the AI determination module 132 is viewed as a low threshold, and the average of the high and low thresholds is viewed as a new threshold in the AI determination module 132. Finally, the AI determination module 132 compares the new threshold and the initial threshold. If the difference between the new threshold and the initial threshold is less than a threshold, the new threshold is determined as an optimum threshold, if not, the AI determination module 132 redetermines an optimum threshold. In this embodiment, only the regions higher than the optimum threshold require the following sharpening treatment for image feature enhancement, thus, over-sharpening is barely visible in the overall image.

In the sub-step 13f of sharpening treatment, the AI determine module 132 applies a sharpening treatment to the pixels with a gray value higher than the optimum threshold in the sharp semiconductor image cut, and output the feature-enhanced image P_{f} which has enhanced edges and details. Because of the previous optimum threshold determination, only some specific regions require to be sharpened, and fine textures or noises in the feature-enhanced image P_{f} will not be over-sharpened.

The AI determination module 132 was trained using etching endpoint images, so it can determine whether the semiconductor device reach the etching endpoint according to the feature-enhanced image P_{f} and output an AI etching endpoint determination signal S_{dAI} which is provided to represent whether the semiconductor device reach the etching endpoint.

With reference to FIG. 1, in the step 14, a determination module 133 of the computing device 130 receives the HV channel etching endpoint determination signal S_{dHV} and the AI etching endpoint determination signal S_{dAI}, and determines whether the semiconductor device reach the etching endpoint according to the HV channel etching endpoint determination signal S_{dHV} and the AI etching endpoint determination signal S_{dAI}. In this embodiment, the HV channel etching endpoint determination signal S_{dHV} and the AI etching endpoint determination signal S_{dAI} are real numbers greater than or equal to 0, the computing device 130 adds the HV channel etching endpoint determination signal S_{dHV} and the AI etching endpoint determination signal S_{dAI} and compares the addition of the signals and an etching endpoint threshold to determine whether the semiconductor device reach the etching endpoint. Preferably, the HV channel etching endpoint determination signal S_{dHV} and the AI etching endpoint determination signal S_{dAI} are multiplied with two weight values and added to become a weighted etching endpoint determination signal, and the determination module 133 determines whether the semiconductor device reach the etching endpoint according to the weighted etching endpoint determination signal.

The HV determination module 131 and the AI determination module 132 in the computing device 130 are provided to process the semiconductor image Pₛ and determine whether the semiconductor device reach the etching endpoint. Accordingly, the present invention can avoid wrong determination of the etching endpoint due to one way determination and improve etching efficiency and manufacture yield.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. An etching endpoint determination method comprising:
etching a semiconductor device using an etching system;
capturing a semiconductor image of the semiconductor device using an optical system;
receiving the semiconductor image from the optical system using a computing device, wherein a HV determination module of the computing device is configured to extract HV channel data of the semiconductor image, determine whether the semiconductor device reach an etching endpoint according to the HV channel data and output a HV channel etching endpoint determination signal, and an AI determination module of the computing device is configured to process the semiconductor image to generate a feature-enhanced image, determine whether the semiconductor device reach the etching endpoint according to the feature-enhanced image and output an AI etching endpoint determination signal; and
receiving the HV channel etching endpoint determination signal and the AI etching endpoint determination signal using a determination module of the computing device, wherein the determination module is configured to determine whether the semiconductor device reach the etching endpoint according to the HV channel etching endpoint determination signal and the AI etching endpoint determination signal.

2. The etching endpoint determination method in accordance with claim 1, wherein the optical system is configured to capture the semiconductor image after the etching system operates over a period of booting time to etch the semiconductor device.

3. The etching endpoint determination method in accordance with claim 1, wherein extraction of the HV channel data of the semiconductor image includes a step of image cutting and gradient enhancement, a step of HV channel processing and adaptive histogram equalization and a step of brightness enhancement.

4. The etching endpoint determination method in accordance with claim 3, wherein in the step of image cutting and gradient enhancement, the HV determination module is configured to cut the semiconductor image to get a semiconductor image cut including only the semiconductor device, configured to compute a horizontal gradient and a vertical gradient of the semiconductor image cut and compute a gradient magnitude using the horizontal and vertical gradients, and configured to enhance a gradient of the semiconductor image cut using the gradient magnitude.

5. The etching endpoint determination method in accordance with claim 4, wherein in the step of HV channel processing and adaptive histogram equalization, the HV determination module is configured to convert RGB pixels of the semiconductor image cut into HSV pixels, configured to divide the semiconductor image cut into a plurality of grids and compute a gray level histogram of each of the plurality of grids, configured to limit a contrast ratio of the gray level histogram of each of the plurality of grids based on a threshold to get a limited gray level histogram of each of the plurality of grids, configured to compute a cumulative distribution function of the limited gray level histogram of each of the plurality of grids, configured to equalize the HSV pixels of each of the plurality of grids using the cumulative distribution function, and configured to perform a interpolation over the HSV pixels located at an edge of each of the plurality of grids to get a equalized semiconductor image.

6. The etching endpoint determination method in accordance with claim 5, wherein in the step of brightness enhancement, the HV determination module is configured to compute a quotient of V components of the pixels in the equalized semiconductor image to V components of the HSV pixels in the semiconductor image cut, and configured to compensate H component of each of the HSV pixels in the semiconductor image cut to become a compensated H component value using the quotient, and wherein the compensated H component value and the V components of the equalized semiconductor image are the HV channel data.

7. The etching endpoint determination method in accordance with claim 6, wherein a sum of the compensated H component value and the V components of the equalized semiconductor image is the HV channel data.

8. The etching endpoint determination method in accordance with claim 6, wherein the HV determination module is configured to perform a moving average treatment on the HV channel data before determining whether the semiconductor device reach the etching endpoint.

9. The etching endpoint determination method in accordance with claim 1, wherein generation of the feature-enhanced image includes a step of Gaussian blur and high-frequency image generation, a step of optimum threshold determination and a step of sharpening treatment.

10. The etching endpoint determination method d in accordance with claim 9, wherein in the step of Gaussian blur and high-frequency image generation, the AI determination module is configured to perform binarization on the semiconductor image to obtain a binarized semiconductor image, configured to cut binarized semiconductor image to obtain a binarized semiconductor image cut including only the semiconductor device, configured to blur the binarized semiconductor image cut using Gaussian blur to obtain a blurred image, configured to extract high-frequency components in the blurred image and add the high-frequency components to the blurred image to obtain a sharp semiconductor image cut.

11. The etching endpoint determination method in accordance with claim 10, wherein in the step of optimum threshold determination, the AI determination module is configured to obtain an initial threshold by computing an average of gray values of all of the pixels in the sharp semiconductor image cut, configured to classify the pixels with a gray value higher than the initial threshold in the sharp semiconductor image cut to a high gray value group and classify the pixels with a gray value lower than the initial threshold in the sharp semiconductor image cut to a low gray value group, configured to obtain a high threshold by computing an average of the gray values of the pixels in the high gray value group and obtain a low threshold by computing an average of the gray values of the pixels in the low gray value group, configured to obtain a new threshold by computing an average of the high and low thresholds, configured to compare the new threshold and the initial threshold, configured to determine the new threshold as an optimum threshold as the difference between the new threshold and the initial threshold is less than a threshold and configured to redetermine an optimum threshold as the difference is not less than the threshold.

12. The etching endpoint determination method in accordance with claim 11, wherein in the step of sharpening treatment, the AI determination module is configured to sharpen the pixels with a gray value higher than the optimum threshold in the sharp semiconductor image cut and output the feature-enhanced image.

13. The etching endpoint determination method in accordance with claim 1, wherein the HV channel etching endpoint determination signal and the AI etching endpoint determination signal are multiplied with two weight values and added to become a weighted etching endpoint determination signal by the determination module of the computing device, and the determination module is configured to determine whether the semiconductor device reach the etching endpoint according to the weighted etching endpoint determination signal.
